(19) United States
(12) Patent Application Publication
(10) Pub. No.: US 2005/0241931 A1
(43) Pub. Date: Nov. 3, 2005

(54) Methods of manufacturing polycrystalline silicon thin film

(75) Inventors: Byung Tae Ahn, Daejeon (KR); Ji Hye Eom, Daejeon (KR)

Correspondence Address: STERNE, KESSLER, GOLDSTEIN & FOX PLLC, 1100 NEW YORK AVENUE, N.W., WASHINGTON, DC, 20005, US

(73) Assignee: Korea Advanced Institute of Science and Technology, Daejeon (KR)

(21) Appl. No.: 11/025,853

(22) Filed: Dec. 30, 2004

(30) Foreign Application Priority Data
Dec. 30, 2003 (KR) 10-2003-0100539

(51) Int. Cl. C23C 16/00; B05D 3/02

(52) U.S. Cl. 204/192.1; 427/372.2; 427/248.1; 428/446

(57) ABSTRACT

The invention is directed to methods of manufacturing a polycrystalline silicon thin film by annealing a substrate and an amorphous silicon thin film in a mixture atmosphere comprising aluminum halide and a second metal. The invention is also directed to a polycrystalline silicon thin film manufactured according to the method of the invention.

### CROSS-REFERENCE TO RELATED APPLICATIONS

This application claims priority to Korean Patent Appl. No. 10-2003-0100539, filed Dec. 30, 2003, which is incorporated by reference herein in its entirety.

### BACKGROUND OF THE INVENTION

1. Field of the Invention

The invention is directed to methods of manufacturing a polycrystalline silicon thin film by annealing a substrate and an amorphous silicon thin film in a mixture atmosphere comprising aluminum halide and a second metal. The invention is also directed to a polycrystalline silicon thin film manufactured according to a method of the invention.

2. Description of the Related Art

For recent fabrication methods of electronic devices, such as TFT Film Transistor) for OLED (Organic Light Emitting Diode), TFT for SRAM (Static Random Access Memory), TFT for EEPROM (Electrically Erasable and Programmable Read Only Memory), solar cells, image sensors, etc., techniques of manufacturing a polycrystalline silicon thin film are becoming increasingly important Thus, research into economically manufacturing the polycrystalline silicon thin film is being vigorously performed.

As such, economical manufacture of the polycrystalline silicon thin film requires a low annealing temperature and a short annealing time period for an annealing process that transforms an amorphous silicon thin film into a polycrystalline silicon thin film.

When amorphous silicon thin film comes into contact with a metal component, the solid-state crystallization temperature needed for the formation of the polycrystalline silicon thin film is lowered. Hence, various methods of lowering the crystallization temperature are under study. For example, there is an annealing process following the direct deposition of a metal, such as copper (Cu), gold (Au), silver (Ag), nickel (Ni), palladium (Pd) or aluminum (Al), on the amorphous silicon thin film, or an annealing process following the spin-coating of a metal solution containing the above metal or metal compound dissolved in an acid onto the silicon thin film.

In particular, aluminum exists at a shallow acceptor level of 0.067 eV in silicon, unlike other metals. Thus, aluminum rarely causes any electric defects due to metal residual, and can be favorably applied to actual devices. Where aluminum is applied to the silicon thin film in a metal solution form, the formation of aluminum oxide prevents the no crystallization-temperature lowering effect (D. K. Shon et al., Japanese J. Applied Physics 35:1005 (1996)). Alternatively, where aluminum metal is directly deposited onto the silicon thin film followed by annealing, the crystallization temperature can be lowered. However, this process is disadvantageous because the polycrystalline silicon thin film is formed by precipitation of crystalline silicons from the aluminum after dissolution of amorphous silicon into the aluminum, and thus, the surface of the thin film becomes uneven. Further, this process results in aluminum remaining after the crystallization, and the concentration of aluminum within the crystallized silicon thin film is too high (M. Shahidul Haque et al, J. Appl. Phys. 75:3928 (1994)).

### SUMMARY OF THE INVENTION

The present invention is directed to a method of manufacturing a polycrystalline silicon thin film by crystallization of an amorphous silicon thin film at a low temperature in a mixture atmosphere comprising aluminum halide and a second metal.

The invention is also directed to a polycrystalline silicon thin film manufactured by the method of the invention.

The present invention provides a method of manufacturing a polycrystalline silicon thin film, capable of lowering the crystallization temperature, unlike the conventional annealing process using the aluminum metal solution, while solving the problems of the process of annealing the aluminum-deposited thin film, by annealing an amorphous silicon thin film in a mixture atmosphere comprising aluminum halide and a second metal.

### BRIEF DESCRIPTION OF THE DRAWINGS

The above and other objects, features and advantages of the present invention will be more clearly understood from the following detailed description taken in conjunction with the accompanying drawings.

FIG. 1A is an X-ray diffraction pattern showing the degree of crystallization of a silicon thin film manufactured according to a conventional adsorption method using an aluminum metal solution.

FIG. 1B is an X-ray diffraction pattern showing the degree of crystallization of a silicon thin film manufactured according to the present invention.

FIG. 2 is a scanning electron microscope showing the silicon grains in the polycrystalline silicon thin film manufactured according to the present invention.

FIG. 3 is a photograph showing a surface roughness of the polycrystalline silicon thin film manufactured according to the present invention.

FIG. 4 is an AES graph of the polycrystalline silicon thin film manufactured according to the present invention.

### DETAILED DESCRIPTION OF THE INVENTION

Based on the present invention, a method of manufacturing a polycrystalline silicon thin film includes forming an amorphous silicon thin film on a substrate and annealing the amorphous silicon thin film formed on the substrate, in which the annealing process is performed in a mixture atmosphere comprising aluminum halide and a second metal.

The formation process of the amorphous silicon thin film on the substrate can be any deposition process, such as but not limited to chemical vapor deposition (CVD), sputtering, or evaporation, so long as the silicon thin film is formed on the substrate. The amorphous silicon thin film formed on the substrate can be from 10 Å to 10 μm in thickness.

The substrate having the silicon thin film can be a glass plate, a quartz plate, a glass plate coated with an amorphous oxide film as an electric insulator, a quartz plate coated with an amorphous oxide film as an electric insulator, or a silicon wafer.

The annealing process of the amorphous silicon thin film can be performed at 400-600° C. using a heating unit or an electromagnetic wave, in the mixture atmosphere comprising aluminum halide and a second metal, mixed in a ratio of 99:1 to 1:99.

Aluminum halide, which is a compound composed of aluminum and a halogen element, includes but is not limited to aluminum chloride (AlCl₃), aluminum iodide (AlI₃), aluminum bromide (AlBr₃), and aluminum fluoride (AIF₃). In some embodiments, the aluminum halide is aluminum chloride (AlCl₃).

Aluminum halide is mixed with a second metal, and the mixture serves as a metal source for metal-induced crystallization. Usable second metal sources, with the exception of aluminum halide, includes gold (Au), silver (Ag), copper (Cu), nickel (Ni), and palladium (Pd), exhibiting metal-induced crystallization effects. As used herein, a second metal includes metal compounds thereof. In the present invention, the metal compound can include but is not limited to AuCl, AgCl, CuCl, CuCl₂, NiCl₂, and PdCl.

If the amorphous silicon thin film is annealed at a temperature lower than 400° C., the time required to form the polycrystalline silicon thin film is increased. If the temperature is higher than 600° C., desired results for the formation of the polycrystalline silicon thin film cannot be expected. Thus, it is preferable that the annealing process of the amorphous silicon thin film be carried out at 400-600° C.

The formation of polycrystalline silicon thin film after annealing the amorphous silicon thin film can be confirmed using Raman spectroscopy or X-ray diffraction (XRD) analysis.

In the present invention, a mixture atmosphere comprising aluminum halide and a second metal mixed in a ratio of 99:1 to 1:99 leads to the formation of the desired polycrystalline silicon thin film.

Before the amorphous silicon thin film is annealed, aluminum halide and a second metal can be mixed at 150-400° C., whereby the mixture atmosphere comprising aluminum halide and a second metal can be uniformly maintained. If the temperature is higher than 400° C., sublimation of aluminum halide occurs quickly, and thus, it is difficult to maintain a constant supply of the aluminum halide and a second metal during the process.

Further, prior to providing the mixture atmosphere comprising aluminum halide and a second metal to the substrate of the amorphous silicon thin film for the annealing process, an inert atmosphere or vacuum atmosphere can be additionally formed in the present method. Thereby, aluminum, which is an easily oxidizable element, is prevented from oxidation, and thus, the annealing process can be effectively performed. For the inert atmosphere, any inert gas can be used, such as but not limited to nitrogen, argon, helium, neon and krypton.

The annealing process of the present invention for crystallization of the amorphous silicon thin film can include a first annealing process performed at 400-600° C. for 0.1-5 hours for nucleation of the amorphous silicon thin film, and a second annealing process performed at 400-900° C. for 0.1-10 hours in the inert atmosphere or vacuum atmosphere for promotion of grain growth after the first annealing process. The desired polycrystalline silicon thin film can result from the first and second annealing processes under the temperature and time period conditions mentioned above, with various conditions for annealing heat-treatment.

The present invention is also directed to a polycrystalline silicon thin film manufactured by the method of the present invention.

Now, the present invention will be described in more detail with reference to the following Examples. These Examples are provided only for illustrating the present invention and should not be construed as limiting the scope and spirit of the present invention.

### COMPARATIVE EXAMPLE

A silicon wafer having silicon oxide formed through a thermal-oxidation process was used as a substrate. A 1000 Å thick amorphous silicon thin film was deposited onto the substrate by an LPCVD (low pressure chemical vapor deposition) process while providing SiH₄ gas at a substrate temperature of 550° C.

As a metal source, aluminum was deposited on the amorphous silicon thin film using an aluminum metal solution form, and then the annealing process was performed at 550° C. for 5 hours (D. K. Shon et al., Japanese J. Applied Physics 35: 1005 (1996)).

### EXAMPLE

A silicon wafer having silicon oxide formed through a thermal-oxidation process was used as a substrate. A 1000 Å thick amorphous silicon thin film was deposited onto the substrate by an LPCVD process while providing SiH₄ gas at a substrate temperature of 550° C.

As a metal source, a mixture of AlCl₃ and NiCl₂ powder mixed in a ratio of 10:1 at 300° C. was used. Then, the amorphous silicon thin film was annealed at 480° C. for 5 hours in an argon (Ar) atmosphere using the above metal source.

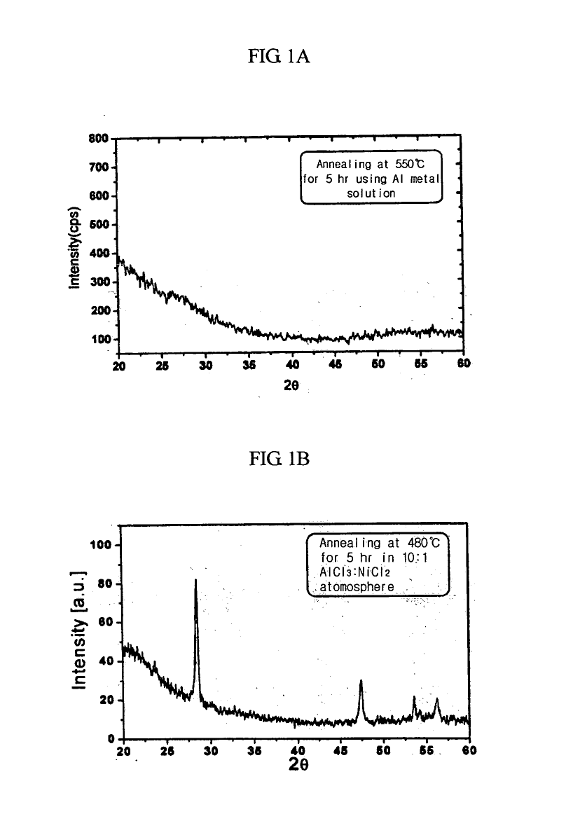

FIG. 1A shows the X-ray diffraction pattern of the silicon thin film annealed at 550° C. for 5 hours by supplying aluminum using a conventional metal solution according to Comparative Example. FIG. 1B shows the X-ray diffraction pattern of the silicon thin film annealed at 480° C. for 5 hours in the mixture atmosphere comprising aluminum chloride (AlCl₃) and nickel chloride (NiCl₂) mixed in a ratio of 10:1, according to Example of the present invention. From these drawings, it can be seen that the silicon thin film annealed at 480° C. for 5 hours according to the present method has distinct peaks (111), (220), (311), while the silicon thin film according to the conventional method has no peaks after annealing process performed at 550° C. for 5 hours. No peak means that the amorphous silicon thin film was not crystallized.

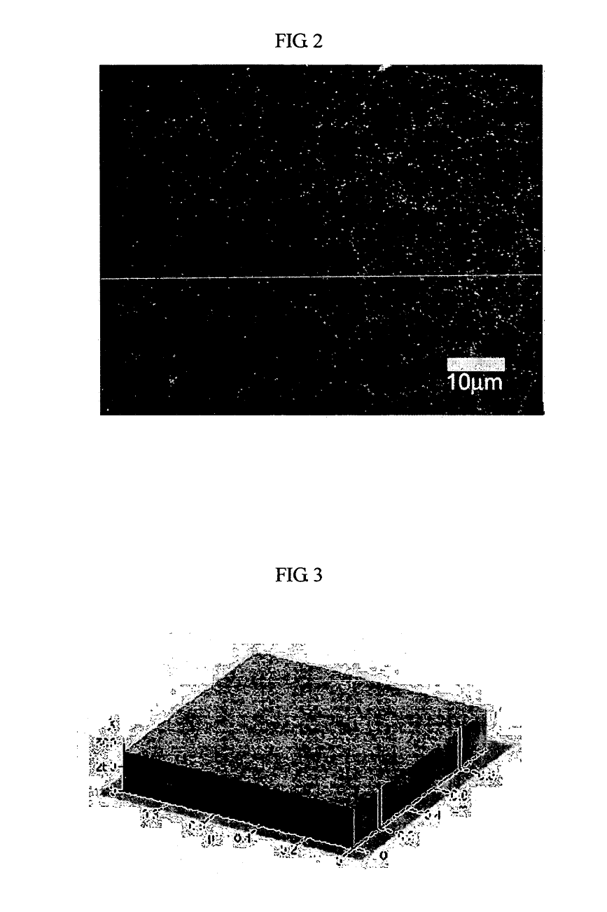

FIG. 2 shows a scanning electron microscope (SEM) image showing the silicon grains in the polycrystalline silicon thin film annealed at 480° C. for 10 hours for manufacturing the silicon thin film, according to Example of the present invention. The grain size in the firm is about 15 μm and is very uniform.

FIG. 3 shows an atomic force microscopy (AFM) surface image of the silicon thin film annealed at 480° C. for 10 hours for manufacturing the polycrystalline silicon thin film, according to Example of the present invention. As shown in the drawing, the annealed thin film which has a surface roughness of less than 5 Å on average appears to be very flat.

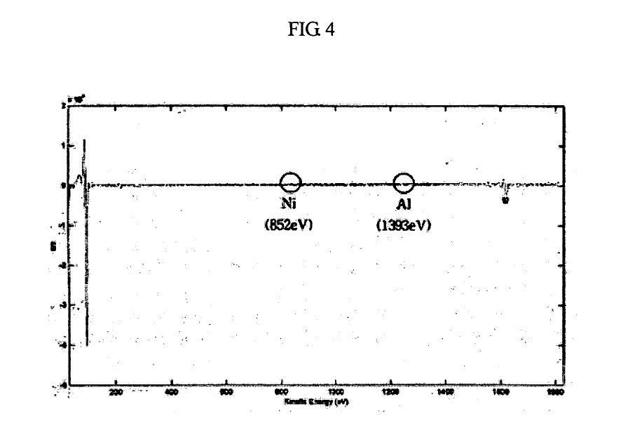

FIG. 4 shows an Auger Electron Spectroscopy (AES) of the silicon thin film annealed at 480° C. for 5 hours according to Example, in which an AES analytic method functions to detect impurities of up to 1%. When the amount of aluminum is 1% or more, the aluminum peak is observed at 1393 eV. When the amount of nickel is 1% or more, the nickel peak is observed at 852 eV. As the result of analyzing the polycrystalline silicon thin film crystallized as in Example of the present invention, no aluminum peak and nickel peak are observed. From this, it can be confirmed that the amount of metal can be limited to 1% or less in the crystallized silicon thin film.

As described above, the present invention provides a method of manufacturing a polycrystalline silicon thin film in a mixture atmosphere comprising aluminum halide and a second metal or metal compound thereof. The method of the present invention to manufacture the polycrystalline silicon thin film is advantageous because the crystallization occurs at a lower temperature, the grain size is much larger, a much smaller amount of the metal remains in the crystallized silicon thin film, and the surface is flatter, compared to conventional crystallization annealing methods.

These examples illustrate possible methods of the present invention. While the invention has been particularly shown and described with reference to some embodiments thereof, it will be understood by those skilled in the art that they have been presented by way of example only, and not limitation, and various changes in form and details can be made therein without departing from the spirit and scope of the invention. Thus, the breadth and scope of the present invention should not be limited by any of the above-described exemplary embodiments, but should be defined only in accordance with the following claims and their equivalents.

All documents cited herein, including journal articles or abstracts, published or corresponding U.S. or foreign patent applications, issued or foreign patents, or any other documents, are each entirely incorporated by reference herein, including all data, tables, figures, and text presented in the cited documents.

1. A method of manufacturing a polycrystalline silicon thin film, comprising:
forming an amorphous silicon thin film on a substrate; and
annealing the formed amorphous silicon thin film on the substrate in a mixture atmosphere comprising aluminum halide and a second metal.

2. The method of claim 1, wherein the amorphous silicon thin film has a thickness of from 10 Å to 10 μm on the substrate.

3. The method of claim 1, wherein the amorphous silicon thin film is formed using chemical vapor deposition, sputtering or evaporation.

4. The method of claim 1, wherein the substrate is selected from the group consisting of a glass plate, a quartz plate, a glass plate coated with an amorphous oxide film as an electric insulator, a quartz plate coated with an amorphous oxide film as an electric insulator, and a silicon wafer.

5. The method of claim 1, wherein the aluminum halide is selected from the group consisting of AlCl₃, AlI₃, AlBr₃ and AlF₃.

6. The method of claim 1, wherein a second metal is selected from the group consisting of Au, Ag, Cu, Ni, Pd, and a compound thereof.

7. The method of claim 1, wherein the aluminum halide and the second metal are mixed in a ratio of 99:1 to 1:99.

8. The method of claim 1, wherein the annealing is performed at 400-600° C.

9. The method of claim 1, wherein the annealing is performed by a heating unit or an electromagnetic wave.

10. The method of claim 1, wherein the mixture atmosphere comprises the aluminum halide and the second metal mixed at 150-400° C., before the annealing.

11. The method of claim 1, further comprising forming an inert atmosphere or vacuum atmosphere before providing the mixture atmosphere comprising the aluminum halide and the second metal or metal compound thereof to the substrate of the amorphous silicon thin film for the annealing.

12. The method of claim 1, wherein the annealing comprises:
a first annealing at 400-600° C. for 0.1-5 hours for nucleation of the amorphous silicon thin film, and
a second annealing at 400-900° C. for 0.1-10 hours in an inert atmosphere or vacuum atmosphere for promotion of grain growth after the first annealing.

13. A polycrystalline silicon thin film, manufactured according to claim 1.
